(19) United States
(12) Patent Application Publication
(10) Pub. No.: US 2011/0216506 A1
(43) Pub. Date: Sep. 8, 2011

(54) HEAT SINK BUCKLE

(75) Inventor: Robert Liang, Taoyuan (TW)

(73) Assignee: Malico Inc., Taoyuan Hsien (TW)

(21) Appl. No.: 12/715,628

(22) Filed: Mar. 2, 2010

(51) Int. Cl. H05K 7/20

(52) U.S. Cl. 361/704

(57) ABSTRACT

A heat sink buckle is provided. The heat sink buckle includes a frame and a side plate. The frame includes a plurality of frame sides. The side plate is substantially perpendicular with the frame, and is configured extending from one of the frame sides. A central portion of the side plate is jointly connected to the frame side. The side plate includes a pressing member and a fixing member. The pressing member is positionally higher than the frame side and the fixing member is positionally lower than the frame side. The fixing member has an inner side surface. The fixing member includes a clasp extruded from a bottom edge of the inner side surface of the fixing member. When the pressing member is inwardly pressed, the fixing member is outwardly widened, and when the pressing member is released, the fixing member recovers to the original position.

### BACKGROUND OF THE INVENTION

1. Field of the Invention

The present invention relates generally to a heat sink buckle, and more particularly, to a heat sink buckle adapted for conveniently locking a heat sink to a chipset and unlocking the heat sink from the chipset.

2. The Prior Arts

Typically, a chipset of a computer, such as a ball grid array (BGA) package, a quad flat package (QFP), and a CPU, generates a lot of heat when being operated. The heat generated must be dissipated out; otherwise the performance of the chipset will be adversely affected, or even burned out. Specifically, those chipsets having higher operational speed usually generate more heat that will cause a more serious problem. Accordingly, a computer host must be equipped with a heat dissipation device for dissipating the heat generated from the chipsets.

A typical heat dissipation device usually includes a fan and a heat sink. The heat sink has a plurality of fins made of a metal material having a high thermal conductivity. The metal material is usually selected from copper and aluminum. The heat sink is closely attached to a surface of a heat generation element, such as a chipset, to conduct the heat generated by the heat generation element to an end of the heat sink. The fan blows air toward the heat sink, thus dissipating the heat to an ambient environment in a convection manner. In such a way, the heat generation element can be normally maintained operating under a certain operation temperature.

In order to closely attach the heat sink to the surface of the chipset, a heat sink buckle is often employed for locking the heat sink onto the chipset. As shown in FIG. 1A, it is a perspective view of a conventional heat sink buckle. A heat sink buckle 1a includes a frame 10a, a side plate 11a, and engaging bars 12a. The frame 10a further includes a plurality of holes 13a configured at where the frame 10a is jointly connected with the side plate 11a. The side plate 11a further includes a protrusion member 14a.

FIG. 1B is a schematic diagram showing the conventional heat sink buckle and the heat sink to be locked by the heat sink buckle to a chipset. A heat sink 15a includes a plurality of fins 120a. Referring to FIG. 1B, the heat sink buckle 1a is fixed to the heat sink 15a by engaging the engaging bars 12a to the fins 120a, so as to fixing the fins 15a in position. The protrusion member 14a is then engaged with an edge of the chipset 16a. In such a way, the bottom surface of the heat sink 15a can be closely attached to the upper surface of the chipset 16a as desired, so as to favorably dissipating the heat generated by the chipset 16a.

However, the conventional heat sink buckle is inconvenient to use. Particularly, the frame 10a of the heat sink buckle 1a is usually thick and strong so as to need to apply a strong force to fix the heat sink 15a with the chipset 16a. As such, when the heat sink 15a is to be unlocked from the chipset 16a, it is hard to detach the heat sink buckle 1a merely by fingers. In fact, a screw driver is often used to insert the hole of frame 10a, and then outwardly push in a reverse direction relative to the direction of assembling. As such, the unlock operation is rather complicated, and may sometimes damage the chipset. Accordingly, it is desired to design a heat sink buckle adapted for conveniently locking and unlocking

### SUMMARY OF THE INVENTION

Accordingly, a primary objective of the present invention is to provide a heat sink buckle adapted for locking a heat sink onto a chipset. When the heat sink buckle is used to lock a heat sink onto the chipset or unlock the heat sink from the chipset, only a single hand is required to press the heat sink buckle for conveniently completing the locking or unlocking operation. The operation of the heat sink buckle does not need additional tools, and is simple and convenient.

For achieving the foregoing objective and others, the present invention provides a heat sink buckle. The heat sink buckle includes a frame and a side plate. The frame includes a plurality of frame sides. The side plate is substantially perpendicular with the frame, and is configured extending from one of the frame sides. A central portion of the side plate is jointly connected to the frame side. The side plate includes a pressing member and a fixing member. The pressing member is positionally higher than the frame side and the fixing member is positionally lower than the frame side. The fixing member has an inner side surface. The fixing member includes a clasp extruded from a bottom edge of the inner side surface of the fixing member. When the pressing member is inwardly pressed, the fixing member is outwardly widened, and when the pressing member is released, the fixing member recovers to the original position.

### BRIEF DESCRIPTION OF THE DRAWINGS

The present invention will be apparent to those skilled in the art by reading the following detailed description of preferred embodiments thereof, with reference to the attached drawings, in which:

FIG. 1A is a perspective view of a conventional heat sink buckle;

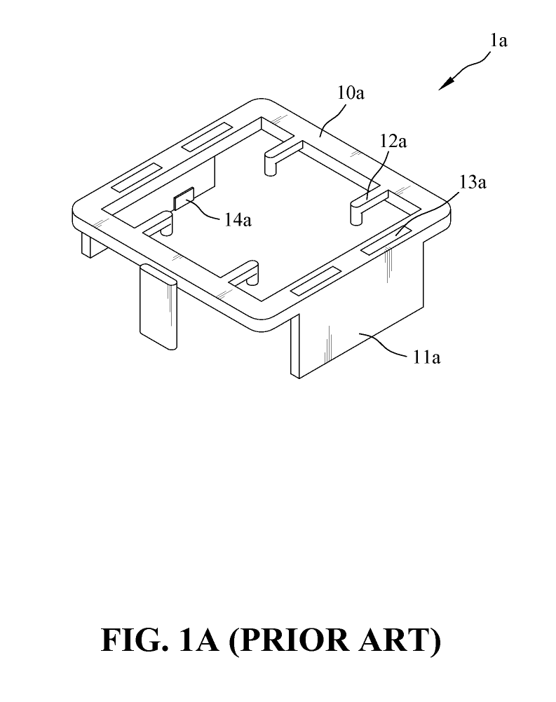

FIG. 1B is a schematic diagram showing the conventional heat sink buckle and the heat sink to be locked by the heat sink buckle to a chipset;

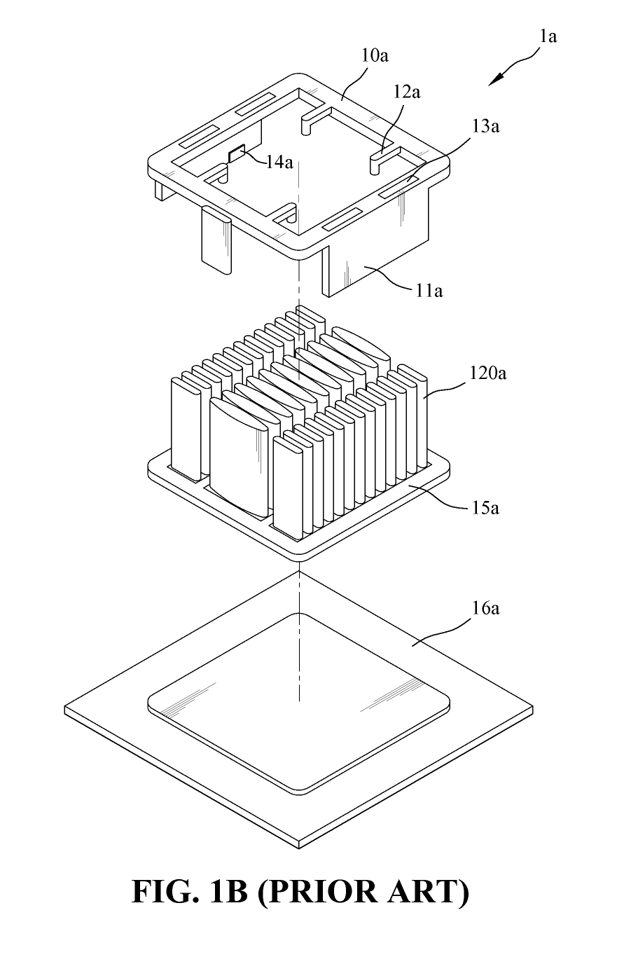

FIG. 2 is an exploded view of a heat sink buckle according to an embodiment of the present invention;

FIG. 3 is an assembled view of the heat sink buckle of FIG. 2;

FIG. 4 is a cross-sectional view illustrating the heat sink buckle to be assembled to the chipset according to an embodiment of the present invention;

FIG. 5 is a cross-sectional view of the heat sink buckle locking the heat sink to the chipset;

FIG. 6 illustrates a first embodiment of the heat sink buckle of the present invention;

FIG. 7 illustrates a second embodiment of the heat sink buckle of the present invention; and

FIG. 8 illustrates a third embodiment of the heat sink buckle of the present invention.

### DETAILED DESCRIPTION OF THE PREFERRED EMBODIMENT

The accompanying drawings are included to provide a further understanding of the invention, and are incorporated in and constitute a part of this specification. The drawing illustrates embodiments of the invention and, together with the description, serves to explain the principles of the invention.

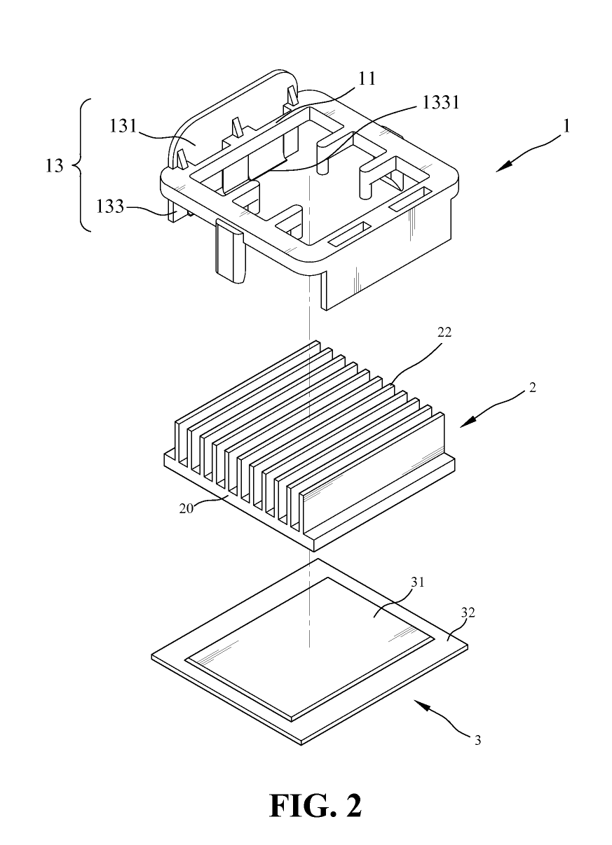

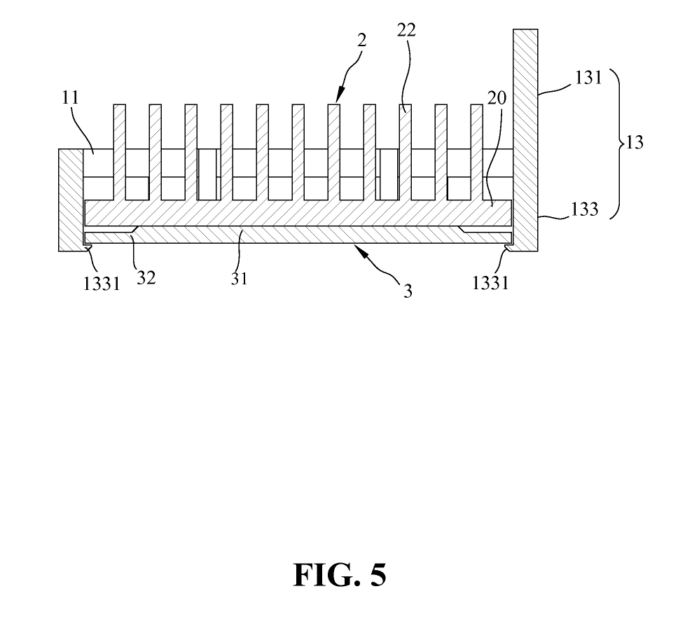

FIG. 2 is an exploded view of a heat sink buckle according to an embodiment of the present invention. FIG. 5 is a cross-sectional view of the heat sink buckle locking the heat sink to the chipset. Referring to FIGS. 2 and 5, the heat sink buckle includes a frame 1 and a side plate 13. The frame 1 is preferably designed with a shape corresponding to either a shape of a heat sink or a shape of a chipset. As shown in FIGS. 2 and 5 and exemplified the current embodiment, the frame 1 is rectangular shaped, and includes four frame sides 11. The side plate 13 is substantially perpendicular with the frame 1 and is configured extending from at least one frame side 11. A central portion of the side plate 13 is jointly connected to the frame side 11. The side plate 13 includes a pressing member 131 and a fixing member 133. The pressing member 131 is positionally higher than the frame 1 and the fixing member is positionally lower than the frame 1. The pressing member 131 is adapted for being pressed by a finger or by an alternative approach.

The fixing member 133 has an inner side surface. The fixing member 133 includes a clasp 1331 extruded from a bottom edge of the inner side surface of the fixing member 133. When the pressing member 131 is inwardly pressed, the fixing member 133 is outwardly widened, and when the pressing member 131 is released, the fixing member 133 recovers to the original position.

As shown in FIG. 2, there are further shown a typical heat sink 2 and a chipset 3. As exemplified in the instant embodiment, the heat sink 2 is an aluminum extrusion heat conduction and dissipation device. The heat sink 2 includes a base 20 and a plurality of heat dissipation fins 22. The heat dissipation fins 22 are parallel with each other and are disposed on the base 20. The chipset 3 includes a chip and a carrier 32.

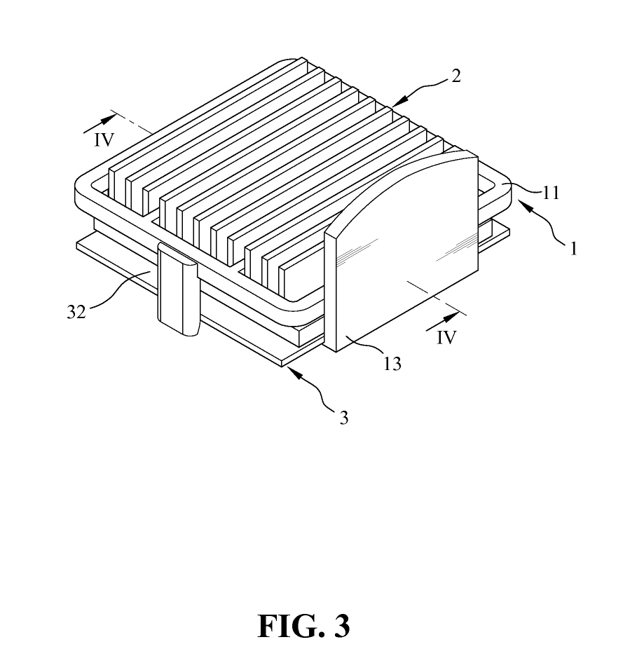

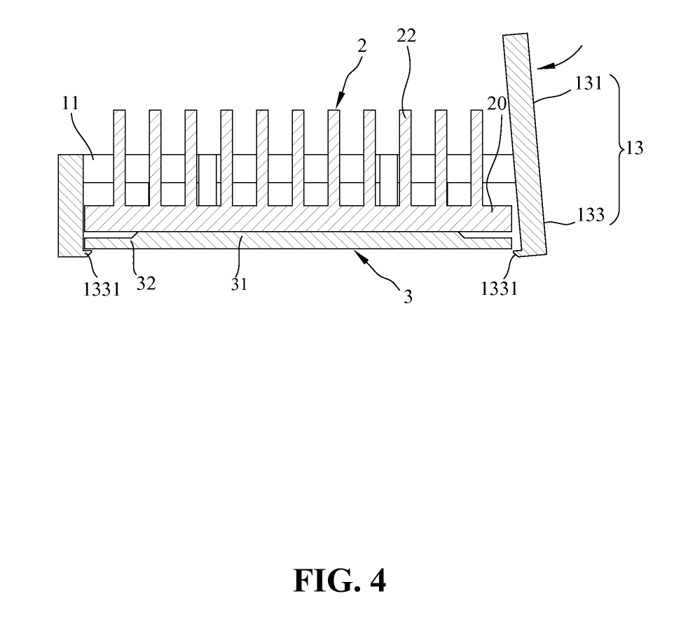

FIG. 3 is an assembled view of the heat sink buckle of FIG. 2. FIG. 4 is a cross-sectional view illustrating the heat sink buckle to be assembled to the chipset according to an embodiment of the present invention. Further referring to FIGS. 3 and 4, in operation, the heat sink buckle 1 is used to lock the heat sink 2 onto the chipset 3. During the locking operation, the heat sink 2 is put on the chipset 3 at first, such that the chip 31 gets in direct contact with a bottom surface of the base 20 of the heat sink 2. Then, the heat sink buckle 1 is covered on the heat sink 2. Specifically, in accordance with the instant embodiment, when the heat sink buckle 1 is covered on the heat sink 2, the pressing member 131 is being inwardly pressed and the fixing member 133 remains outwardly widened, so that the heat sink 2 is allowed to be inserted through the widened fixing member 133 of the heat sink buckle 1. Meanwhile, the clasp 1331 is positioned corresponding to the edge of the carrier 32. Then, the pressing member 131 is released, so that the clasp 1331 clasps the edge of the carrier 32, thus locking the heat sink 2 onto the chipset 3. Similarly, when one intends to unlock the heat sink 2 from the chipset 3, he can simply presses the pressing member 131 of the heat sink buckle 1 to widen the fixing member 133, and then detaches the heat sink 2 from the chipset 3.

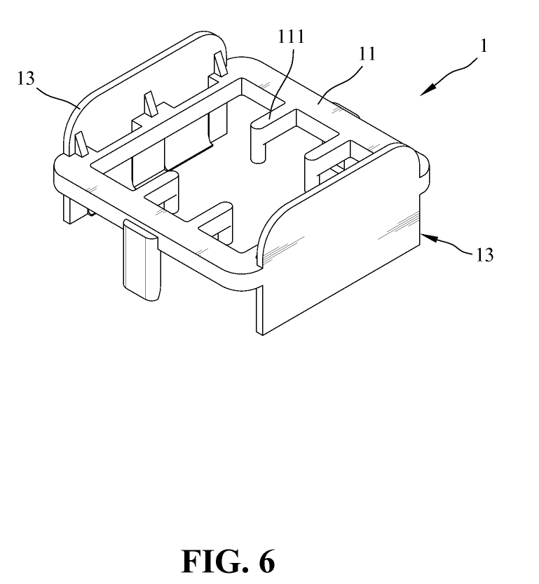

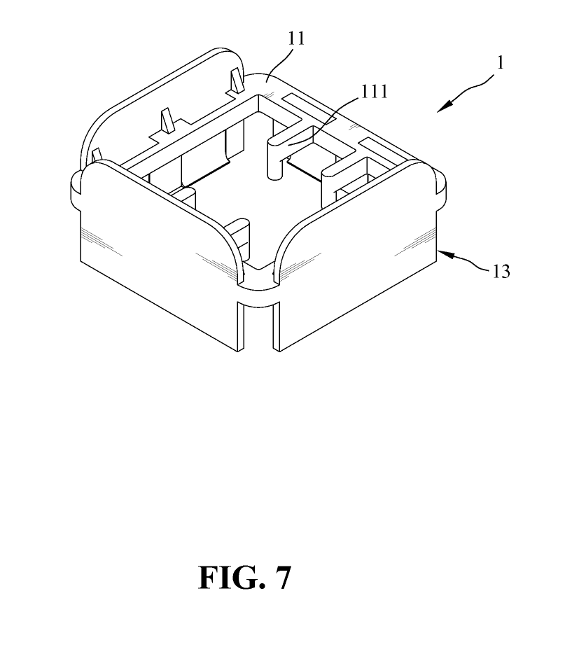

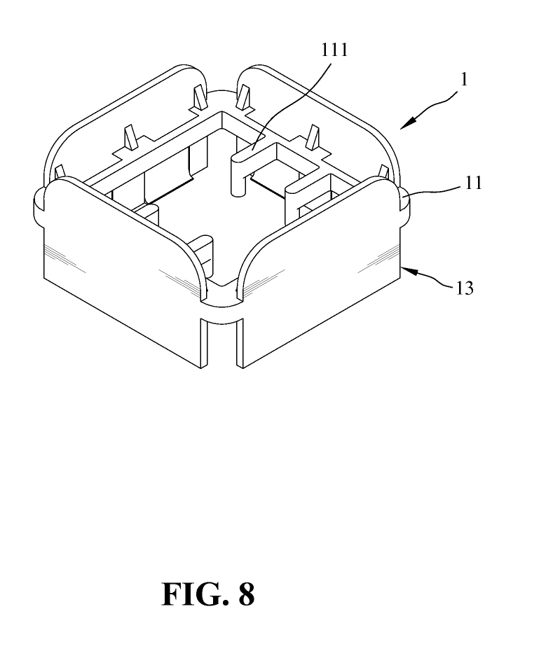

FIG. 6 illustrates a first embodiment of the heat sink buckle of the present invention. Referring to FIG. 6, the heat sink buckle 1 includes two side plates 13. The two side plates are substantially perpendicular with two opposite frame sides 11 of the frame 1. In addition to the two opposite frame sides 11, the frame 1 further includes two frame sides 11, on which the frame 1 further includes two elastic bars inwardly extending for improving the stability of fixing the heat sink 2. FIG. 7 illustrates a second embodiment of the heat sink buckle of the present invention. FIG. 8 illustrates a third embodiment of the heat sink buckle of the present invention. Referring to FIGS. 7 and 8, the present invention can also be modified to include three side plates 13 substantially perpendicular with three frame sides 11, or four side plates 13 substantially perpendicular with four frame sides 11. The quantity of the side plates 13 is not a restriction for the protection scope of the present invention.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A heat sink buckle, adapted for locking a heat sink onto a chipset, comprising:
a frame comprising a plurality of frame sides; and
at least one side plate being substantially perpendicular with the frame and configured extending from one of the frame sides, wherein a central portion of the side plate is jointly connected to the frame side, wherein the side plate comprises:
a pressing member, positionally higher than the frame; and
a fixing member, positionally lower than the frame, wherein the fixing member has an inner side surface, and the fixing member comprises a clasp extruded from a bottom edge of the inner side surface of the fixing member.

2. The heat sink buckle as claimed in claim 1, wherein the frame has a shape corresponding to a shape of the heat sink or corresponding to a shape of the chipset.
